(19) United States
(12) Patent Application Publication
(10) Pub. No.: US 2025/0081829 A1
(43) Pub. Date: Mar. 6, 2025

(54) DISPLAY DEVICE AND METHOD FOR FABRICATING THE SAME

(71) Applicant: Samsung Display Co., Ltd., Yongin-Si (KR)

(72) Inventors: Sang Duk LEE, Yongin-si (KR); Hoi Kwan LEE, Yongin-si (KR)

(21) Appl. No.: 18/664,321

(22) Filed: May 15, 2024

(30) Foreign Application Priority Data
Aug. 28, 2023 (KR) 10-2023-0113164

(51) Int. Cl. H10K 59/80

(52) U.S. Cl. CPC H10K 59/8792; H10K 59/8793

(57) ABSTRACT

The present disclosure relates to a display device, and more particularly, to a display device capable of preventing a flow of resin for window manufacture, and a method for fabrication thereof. According to an embodiment of the disclosure, a display device comprises a display panel, a polarization plate disposed on the display panel and having a through hole, a hole cover disposed on the polarization plate to cover the through hole of the polarization plate, a light blocking layer disposed on the hole cover and the polarization plate, and a window on the polarization plate, the hole cover, and the light blocking layer. At least a portion of the light blocking layer is disposed between the hole cover and the window.

### CROSS-REFERENCE TO RELATED APPLICATION

This application claims priority from Korean Patent Application No. 10-2023-0113164 filed on Aug. 28, 2023 in the Korean Intellectual Property Office, and all the benefits accruing therefrom under 35 U.S.C. 119, the contents of which in its entirety are herein incorporated by reference.

### BACKGROUND

### 1. Field of the Disclosure

The present disclosure relates to a display device, and more particularly, to a display device capable of preventing a flow of resin for window manufacture, and a method for fabrication thereof.

### 2. Description of the Related Art

Various types of electronic devices, including display modules, are used to provide image information, and electronic devices may include electronic modules that receive external signals or provide output signals to the outside. For example, electronic modules may include camera modules, etc., and the demands for display devices that can obtain high-quality captured images are increasing.

### SUMMARY

Aspects of the present disclosure provide a display device capable of preventing a flow of a resin for window manufacturing and a method for fabrication thereof.

According to an embodiment of the disclosure, a display device comprises a display panel, a polarization plate disposed on the display panel and having a through hole, a hole cover disposed on the polarization plate to cover the through hole of the polarization plate, a light blocking layer disposed on the hole cover and the polarization plate, and a window on the polarization plate, the hole cover, and the light blocking layer. At least a portion of the light blocking layer is disposed between the hole cover and the window.

In an embodiment, the hole cover is disposed between the through hole of the polarization plate and the window.

In an embodiment, the light blocking layer comprises a first light blocking layer disposed on the hole cover and having an opening defining a transmission area of the hole cover, and a second light blocking layer disposed on an edge of the polarization plate.

In an embodiment, the transmission area of the hole cover is disposed above the through hole of the polarization plate.

In an embodiment, the first light blocking layer is disposed on an edge of the hole cover.

In an embodiment, the first light blocking layer and the second light blocking layer are integral.

In an embodiment, the first light blocking layer is further disposed on a side of the hole cover.

In an embodiment, the display device further comprises an adhesive layer disposed between the polarization plate and the hole cover.

In an embodiment, the polarization plate and the hole cover are attached by the adhesive layer.

In an embodiment, the first light blocking layer is further disposed on a side of the adhesive layer.

In an embodiment, the hole cover is made of a transparent material.

In an embodiment, the hole cover includes at least one material selected from transparent glass, transparent acrylic, transparent urethane, and transparent polymethylmethacrylate (PMMA).

In an embodiment, the display panel has a through hole, and the through hole of the display panel is disposed below the through hole of the polarization plate.

In an embodiment, the display device further comprises a passivation layer disposed on a side of the polarization plate with the display panel interposed between the polarization plate and the passivation layer.

In an embodiment, the passivation layer has a through hole, and the through hole of the passivation layer is disposed below the through hole of the polarization plate.

According to an embodiment of the disclosure, a method of manufacturing a display device comprises placing a polarization plate having a through hole on a display panel, placing a hole cover on the polarization plate to cover the through hole of the polarization plate, placing a light blocking layer on the polarization plate and the hole cover, and placing a window on the light blocking layer. At least a portion of the light blocking layer is disposed between the hole cover and the window.

In an embodiment, the hole cover is disposed between the through hole of the polarization plate and the window.

In an embodiment, the placing of the light blocking layer comprises: placing a first light blocking layer having an opening defining a transmission area of the hole cover on the hole cover, and placing a second light blocking layer on an edge of the polarization plate.

In an embodiment, the transmission area of the hole cover is disposed above the through hole of the polarization plate.

In an embodiment, the first light blocking layer is disposed on an edge of the hole cover.

In an embodiment, the first light blocking layer and the second light blocking layer are integrally formed.

In an embodiment, the placing the light blocking layer further comprises placing the first light blocking layer on a side of the hole cover.

In an embodiment, the method further comprises placing an adhesive layer on the polarization plate and the hole cover.

In an embodiment, the polarization plate and the hole cover are attached by the adhesive layer.

In an embodiment, the placing the light blocking layer further comprises placing the first light blocking layer on a side of the adhesive layer.

In an embodiment, the hole cover is made of a transparent material.

In an embodiment, the hole cover includes at least one material selected from transparent glass, transparent acrylic, transparent urethane, and transparent polymethylmethacrylate (PMMA).

In an embodiment, the placing the window comprises applying a resin on the hole cover, the polarization plate, the first light blocking layer, and the second light blocking layer, and curing the resin.

According to an embodiment of the disclosure, a method of manufacturing a display device comprises placing a polarization plate having a through hole on a display panel, preparing a hole cover member including a first light blocking layer, a hole cover, and an adhesive layer, placing the hole cover member on the polarization plate to cover the through hole of the polarization plate, placing a second light blocking layer on the polarization plate, and placing a window on the first light blocking layer. At least a portion of the first light blocking layer is disposed between the hole cover member and the window.

In an embodiment, the first light blocking layer is disposed on the hole cover to define a transmission area of the hole cover.

In an embodiment, the hole cover is made of a transparent material.

In the display device and a method of manufacturing the same according to the present disclosure, a flow of resin for window manufacturing can be prevented.

### BRIEF DESCRIPTION OF THE DRAWINGS

The above and other aspects and features of the present disclosure will become more apparent by describing in detail exemplary embodiments thereof with reference to the attached drawings.

FIG. 1 is a plan view of a display device according to an embodiment.

FIG. 2 is a cross-sectional view taken along line I-I′ of FIG. 1.

FIG. 3 is a cross-sectional view taken along line II-II′ of FIG. 1.

FIGS. 4, 5, 6, 7, 8, 9, 10, and 11 are views illustrating a method of manufacturing a display device according to an embodiment.

FIGS. 12 and 13 are views illustrating a method of manufacturing a display device according to embodiment.

### DETAILED DESCRIPTION OF THE EMBODIMENTS

The inventive concept will now be described more fully hereinafter with reference to the accompanying drawings, in which embodiments are shown. The inventive concept may, however, be embodied in different forms and should not be construed as limited to the embodiments set forth herein. Rather, these embodiments are provided so that this disclosure will be thorough and complete, and will fully convey the scope of the inventive concept to those skilled in the art.

It will also be understood that when a layer is referred to as being “on” another layer or substrate, it can be directly on the other layer or substrate, or intervening layers may also be present. The same reference numbers indicate the same components throughout the specification. In the attached figures, the thickness of layers and regions is exaggerated for clarity.

Although the terms “first”, “second”, etc. may be used herein to describe various elements, these elements, should not be limited by these terms. These terms may be used to distinguish one element from another element. Thus, a first element discussed below may be termed a second element without departing from teachings of one or more embodiments. The description of an element as a “first” element may not require or imply the presence of a second element or other elements. The terms “first”, “second”, etc. may also be used herein to differentiate different categories or sets of elements. For conciseness, the terms “first”, “second”, etc. may represent “first-category (or first-set)”, “second-category (or second-set)”, etc., respectively.

Features of various embodiments of the present disclosure may be combined partially or totally. As will be clearly appreciated by those skilled in the art, technically various interactions and operations are possible. Various embodiments can be practiced individually or in combination.

Hereinafter, embodiments will be described in detail with reference to the accompanying drawings.

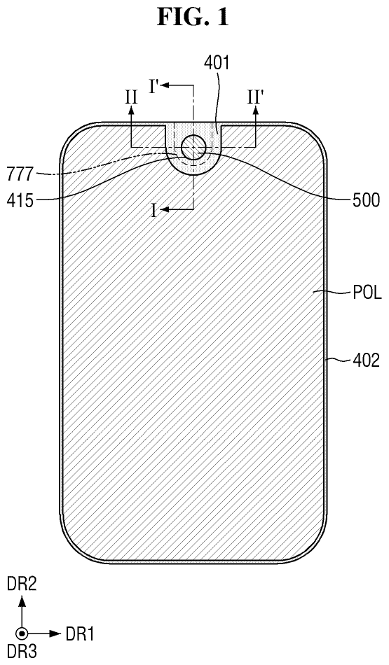

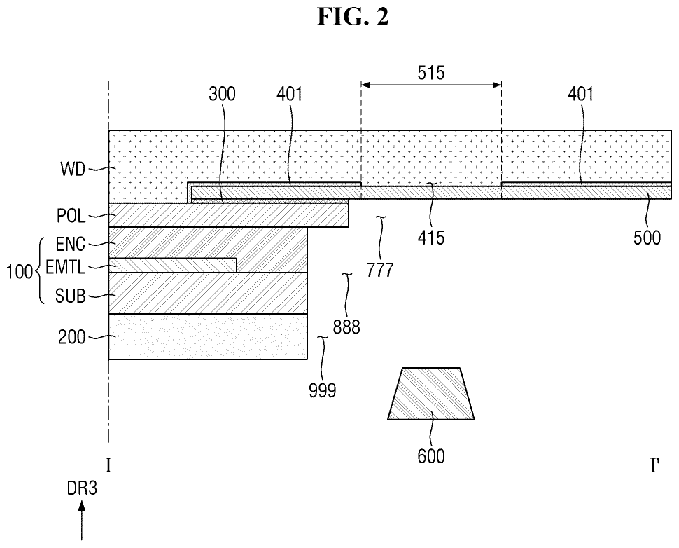

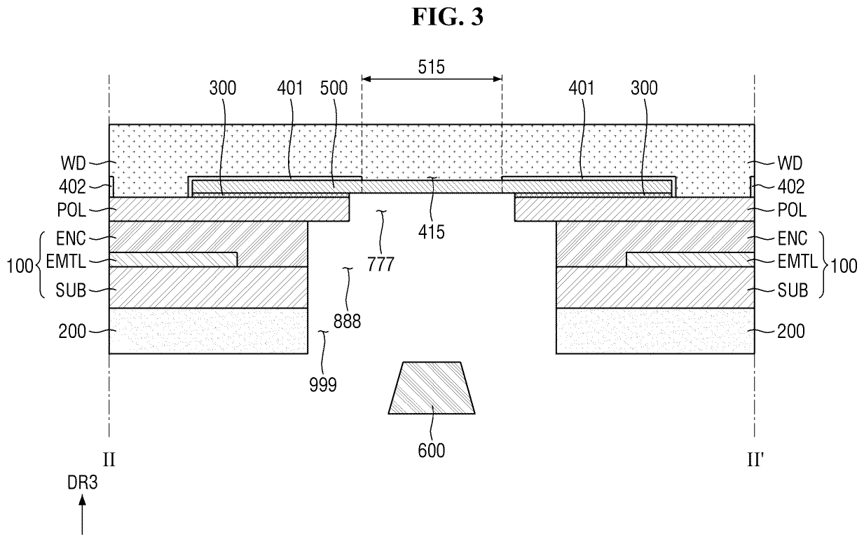

FIG. 1 is a plan view of a display device according to an embodiment. FIG. 2 is a cross-sectional view taken along line I-I′ of FIG. 1. FIG. 3 is a cross-sectional view taken along line II-II′ of FIG. 1.

As illustrated in FIGS. 1 to 3, the display device according to an embodiment may include a display panel 100, a passivation layer 200, a substrate SUB, a light-emitting element layer EMTL, an encapsulation layer ENC, a polarization plate POL, an adhesive layer 300, a hole cover 500, light blocking layers 401 and 402, and a window WD.

The display panel 100 may include the substrate SUB, the light-emitting element layer EMTL, and the encapsulation layer ENC. Meanwhile, although not illustrated, the display panel 100 may further include a transistor layer disposed between the substrate SUB and the light-emitting element layer EMTL, a touch sensing unit disposed on the encapsulation layer ENC, and a color filter layer disposed on the touch sensing unit.

The passivation layer 200 may be disposed below the display panel 100. For example, the passivation layer 200 may be disposed below the substrate SUB. In other words, the passivation layer 200 may be disposed on the lower side of the polarization plate POL with the display panel 100 interposed therebetween. The passivation layer 200 may prevent external light from reaching the display panel 100. In addition, the passivation layer 200 may prevent external impact from being delivered to the bottom of the display panel 100. The passivation layer 200 may have a film form.

The substrate SUB may be disposed on the passivation layer 200. The substrate SUB may be a base substrate or a base member. The substrate SUB may be a flexible substrate that can be bent, folded, or rolled. For example, the substrate SUB may include, but is not limited to, a polymer resin such as polyimide PI. For another example, the substrate SUB may include a glass material or a metal material.

The transistor layer may be disposed on the substrate SUB. The transistor layer may include a plurality of thin-film transistors forming pixel circuits of pixels. The transistor layer may include gate lines, data lines, voltage lines, gate control lines, fan-out lines for connecting a display driver with the data lines, lead lines for connecting the display driver with the pads, etc. Each of the transistors may include a semiconductor region, a source electrode, a drain electrode, and a gate electrode. For example, when a gate driver is formed on one side of a non-display area of the display panel 100, the gate driver may include thin-film transistors.

The transistor layer may be disposed in a display area, a non-display area and a sub-area. The thin-film transistors in each of the pixels, gate lines, data lines and voltage lines in the transistor layer may be disposed in the display area. The gate control lines and the fan-out lines in the transistor layer may be disposed in the non-display area. The lead lines of the transistor layer may be disposed in the sub-area.

The light-emitting element layer EMTL may be disposed on the transistor layer. The light-emitting element layer EMTL may include a plurality of light-emitting elements in each of which a pixel electrode, a light-emitting layer and a common electrode are stacked on one another sequentially to emit light, and a pixel-defining film for defining the pixels. The plurality of light-emitting elements in the light-emitting element layer EMTL may be disposed in the display area.

For example, the light-emitting layer may be an organic light-emitting layer containing an organic material. The light-emitting layer may include a hole transporting layer, an organic light-emitting layer and an electron transporting layer. When the pixel electrode receives a predetermined voltage and the common electrode receives a cathode voltage through the thin-film transistors in the transistor layer, the holes and electrons may move to the organic light-emitting layer through the hole transporting layer and the electron transporting layer, respectively, such that they combine in the organic light-emitting layer to emit light. For example, the pixel electrode may be an anode electrode while the common electrode may be a cathode electrode. It is, however, to be understood that the present disclosure is not limited thereto.

As another example, the light-emitting elements may include quantum-dot light-emitting diodes each including a quantum-dot light-emitting layer, inorganic light-emitting diodes each including an inorganic semiconductor, or micro light-emitting diodes.

The encapsulation layer ENC may cover the upper and side surfaces of the light-emitting element layer EMTL, and may protect the light-emitting element layer EMTL. The encapsulation layer ENC may include at least one inorganic layer and at least one organic layer for encapsulating the light-emitting element layer EMTL.

The touch sensing unit may be disposed on the encapsulation layer ENC. The touch sensing unit may include a plurality of touch electrodes for sensing a user's touch by capacitive sensing, and touch lines connecting the plurality of touch electrodes with a touch driver. For example, the touch sensing unit may sense a user's touch by mutual capacitance sensing or self-capacitance sensing.

For another example, the touch sensing unit may be disposed on a separate substrate disposed on a display unit. In such case, the substrate supporting the touch sensing unit may be a base member encapsulating the display unit.

The plurality of touch electrodes of the touch sensing unit may be disposed in a touch sensor area overlapping the display area. The touch lines of the touch sensing unit may be disposed in a touch peripheral area overlapping the non-display area.

The color filter layer may be disposed on the touch sensing unit. The color filter layer may include a plurality of color filters associated with a plurality of emission areas, respectively. Each of the color filters may selectively transmit light of a particular wavelength and block or absorb lights of other wavelengths. The color filter layer may absorb some of lights introduced from the outside of the display device to reduce the reflection of external light. Accordingly, the color filter layer can prevent distortion of colors due to the reflection of external light.

Since the color filter layer is disposed directly on the touch sensing unit, the display device may require no separate substrate for the color filter layer. Therefore, the thickness of the display device can be relatively reduced.

As illustrated in FIG. 2, the polarization plate POL may be disposed on the encapsulation layer ENC. For example, the polarization plate POL may be disposed on the color filter layer of the display panel 100. The polarization plate POL may include a linear polarization layer and at least one phase retardation layer. The linear polarization layer may be an optical layer that linearly polarizes light provided from the outside in one direction. The phase retardation layer may be a λ/2 phase retardation layer and a λ/4 phase retardation layer. The polarization plate POL can function to reduce reflections caused by external light.

As illustrated in FIGS. 1 to 3, the polarization plate POL may have a through hole 777 passing through it in a third direction DR3. At this time, one side of the through hole 777 may have an open shape. For example, as illustrated in FIG. 1, one side of the through hole 777 may have a shape that is open in a second direction DR2. Accordingly, from a plan view as illustrated in FIG. 1, the through hole 777 may have a U-shape. However, the shape of the through hole 777 of the polarization plate POL is not limited thereto. For example, from a plan view, the through hole 777 of the polarization plate POL may have a closed curve shape such as a ring. In an embodiment, the display panel 100 described above may have a through hole 888 disposed below and to correspond to the through hole 777 of the polarization plate POL. In addition, the passivation layer 200 described above may have a through hole 999 disposed below and to correspond to the through hole 777 of the polarization plate POL.

The adhesive layer 300 may be disposed on the polarization plate POL. The adhesive layer 300 may be, for example, an optically clear adhesive layer.

The hole cover 500 may be disposed on the adhesive layer 300 and the polarization plate POL. The hole cover 500 may be attached to polarization plate POL using the adhesive layer 300. At this time, the hole cover 500 may be disposed on the adhesive layer 300 and the polarization plate POL to cover the through hole 777 of the polarization plate POL. For example, the hole cover 500 may be disposed between the window WD and the through hole 777 of the polarization plate POL. In an embodiment, as illustrated in FIGS. 1 and 3, the hole cover 500 may have a larger area than the through hole 777 so as to completely cover the through hole 777. The hole cover 500 may be made of a transparent material. For example, the hole cover 500 may include at least one material selected from transparent glass, transparent acrylic, transparent urethane, and transparent polymethylmethacrylate (PMMA). In an embodiment, the hole cover 500 may have a light transmittance of, for example, 90% or more. The hole cover 500 can prevent resin, which is a material of the window WD, from flowing through the through hole 777 of the polarization plate POL during the window WD attachment process. In addition, since the hole cover 500 is made of a transparent material, light can normally enter a camera module 600 disposed below the hole cover 500. In an embodiment, the hole cover 500 and the adhesive layer 300 may be attached to each other to form one component (e.g., a hole cover member). In other words, the hole cover 500 and the adhesive layer 300 may be attached to each other and provided as a single component (e.g., the hole cover member). For example, the hole cover member may include the hole cover 500 and the adhesive layer 300.

The light blocking layers 401 and 402 may include a first light blocking layer 401 and a second light blocking layer 402. In an embodiment, the first light blocking layer 401 and the second light blocking layer 402 may be formed integrally.

The first light blocking layer 401 may be disposed on the hole cover 500. The first light blocking layer 401 may have the opening 415 that defines the transmission area 515 of the hole cover 500. The transmission area 515 of the hole cover 500 may be arranged to be above and correspond to the camera module 600. In other words, the opening 415 of the first light blocking layer 401 and the transmission area 515 of the hole cover 500 may be arranged to be above and overlap the lens of the camera module 600. In addition, the first light blocking layer 401 may be disposed on the side of the hole cover 500 and the side of the adhesive layer 300. The first light blocking layer 401 may be formed on the hole cover 500 using a printing method. The first light blocking layer 401 may be a printing layer containing pigment or dye. The first light blocking layer 401 may have a black color. However, the present disclosure is not limited thereto, and the first light blocking layer 401 includes a material that blocks light, and its color is not limited to black. In an embodiment, the adhesive layer 300, the hole cover 500, and the first light blocking layer 401 may be attached to each other to form one component (e.g., a hole cover member). In other words, the adhesive layer 300, the hole cover 500, and the first light blocking layer 401 may be attached to each other and provided as single component (e.g., the hole cover member). For example, the hole cover member may include the hole cover 500, the adhesive layer 300, and the first light blocking layer 401.

The transmission area 515 of the hole cover 500 and the opening 415 of the first light blocking layer 401 may be disposed to be above and correspond to the through hole 777 of the polarization plate POL described above. In other words, the transmission area 515 of the hole cover 500 and the opening 415 of the first light blocking layer 401 may be above and overlap the through hole 777 of polarization plate POL described above.

The second light blocking layer 402 may be disposed on the edge of the polarization plate POL. For example, the second light blocking layer 402 may be disposed along the edge of the polarization plate POL. The second light blocking layer 402 may be formed on the polarization plate POL using a printing method. The second light blocking layer 402 may be made of the same material as the first light blocking layer 401 described above.

The window WD may be disposed on the polarization plate POL, the hole cover 500, the first light blocking layer 401, and the second light blocking layer 402. The window WD may be made of transparent glass or transparent resin.

The camera module 600 may be disposed below the passivation layer 200. For example, the camera module 600 may be disposed to correspond to the through hole 999 of the passivation layer 200. The camera module 600 may receive light from the outside through the through hole 999 of the passivation layer 200, the through hole 888 of the display panel 100, and the through hole 777 of the polarization plate POL.

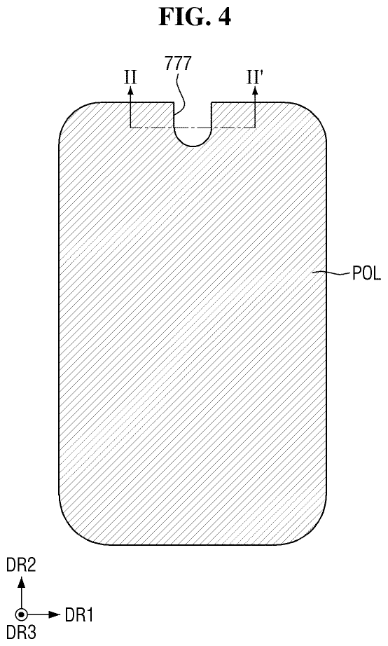

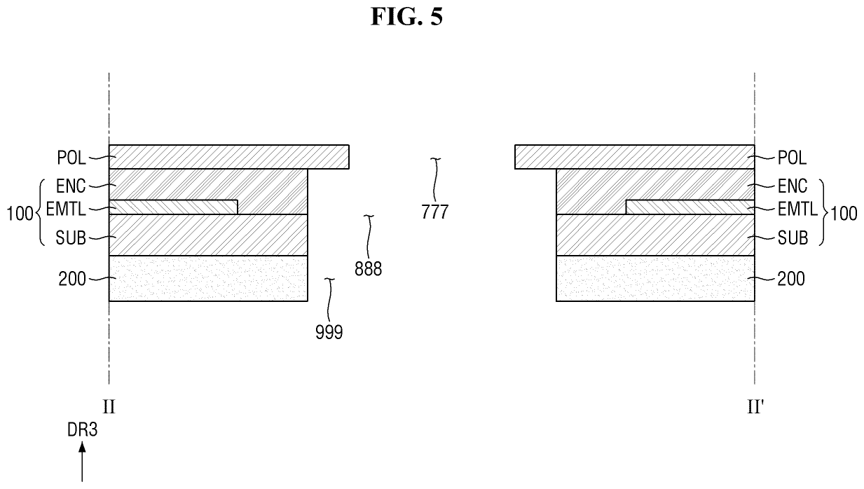

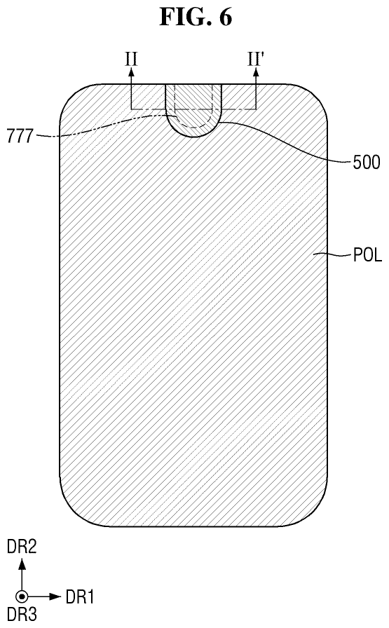

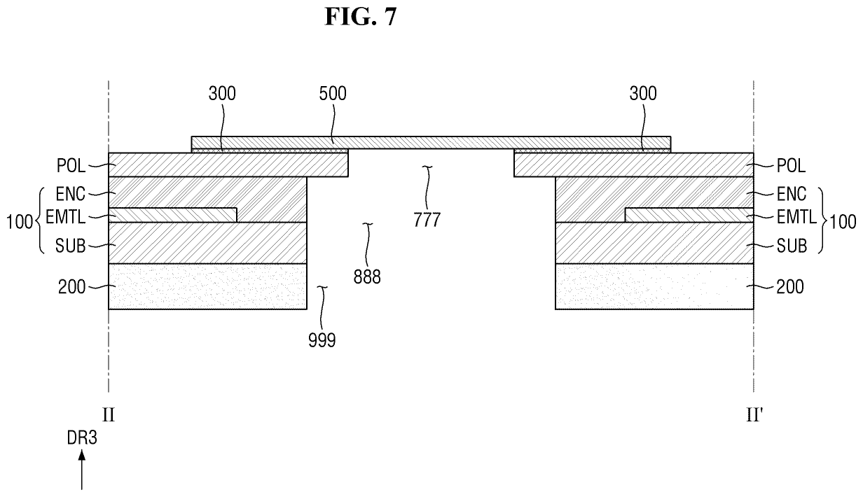

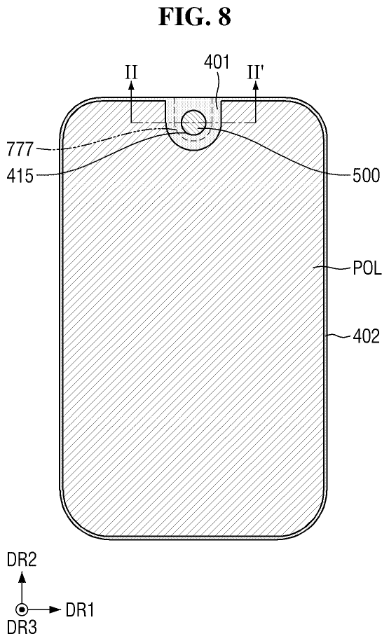

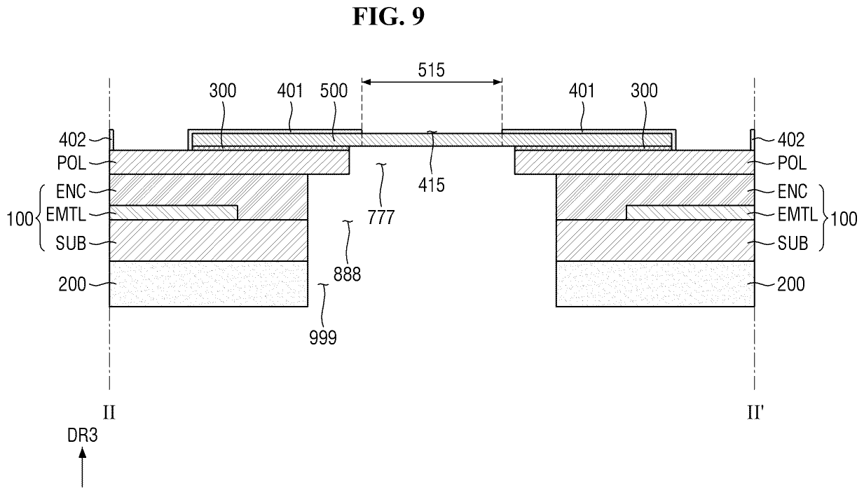

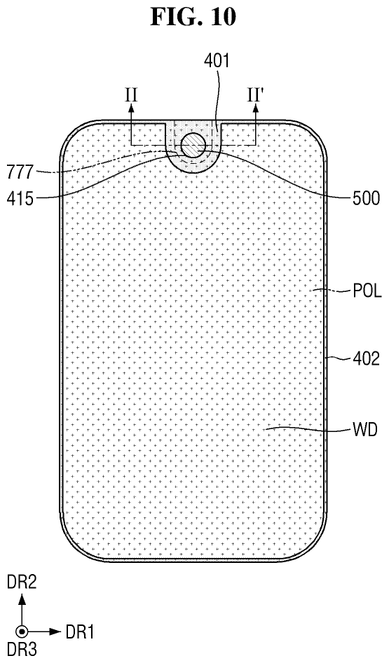

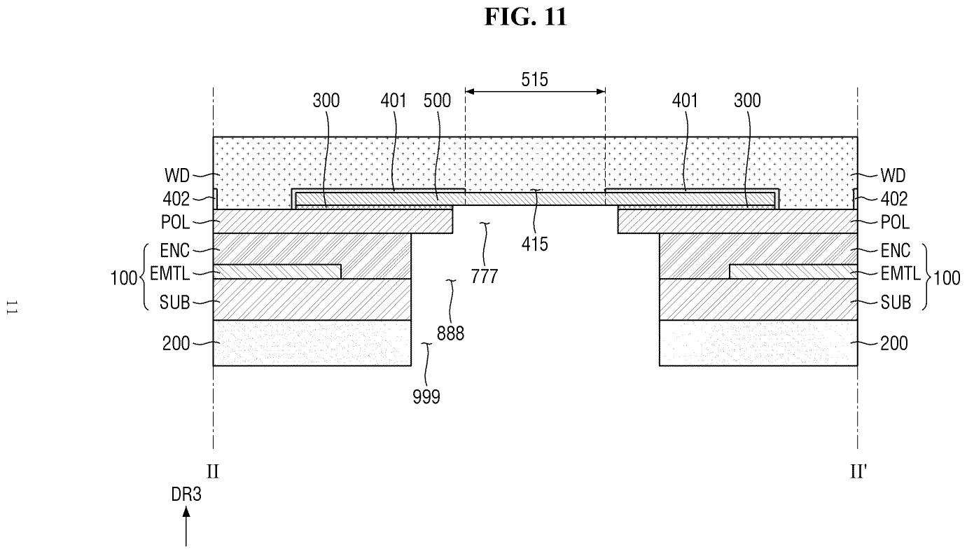

FIGS. 4 to 11 are views illustrating a method of manufacturing a display device according to an embodiment. Here, FIG. 5 is a cross-sectional view taken along line II-II′ of FIG. 4, FIG. 7 is a cross-sectional view taken along line II-II′ of FIG. 6, FIG. 9 is a cross-sectional view taken along line II-II′ of FIG. 8, and FIG. 11 is a cross-sectional view taken along line II-II′ of FIG. 10.

First, as illustrated in FIGS. 4 and 5, a passivation layer 200 may be disposed on the lower surface of a display panel 100, and a polarization plate POL may be disposed on the upper surface of the display panel 100. For example, the passivation layer 200 is disposed on the lower surface of a substrate SUB provided in the display panel 100, and the polarization plate POL is disposed on an encapsulation layer ENC provided in the display panel 100. Meanwhile, when the touch sensing unit and color filter layer described above are further disposed on the encapsulation layer ENC, the polarization plate POL described above may be disposed on the color filter layer.

Subsequently, as illustrated in FIGS. 6 and 7, after the adhesive layer 300 is disposed on the polarization plate POL, a hole cover 500 may be disposed on the adhesive layer 300. At this time, the hole cover 500 may be placed on the polarization plate POL so as to completely cover the through hole 777 of the polarization plate POL. In an embodiment, the adhesive layer 300 may be provided in a state of being attached (or adhered) to the lower surface of the hole cover 500. In other words, one surface of the adhesive layer 300 may be provided in a state of being attached to the lower surface of the hole cover 500. The other side of the adhesive layer 300 may be attached to the polarization plate POL.

Thereafter, as illustrated in FIGS. 8 and 9, light blocking layers 401 and 402 may be disposed on the hole cover 500 and the polarization plate POL. For example, a first light blocking layer 401 defining a transmission area 515 of the hole cover 500 is disposed on the hole cover 500, and a second light blocking layer 402 may be disposed on the polarization plate POL along an edge of the polarization plate POL.

Next, as illustrated in FIGS. 10 and 11, a window WD may be disposed on the hole cover 500, the polarization plate POL, the first light blocking layer 401, and the second light blocking layer 402. For example, after the resin used in manufacturing the window WD is applied on the hole cover 500, the polarization plate POL, the first light blocking layer 401, and the second light blocking layer 402, the resin may be cured when light is irradiated onto the applied resin, thereby forming the window WD. At this time, since the through hole 777 of the polarization plate POL may be covered by the hole cover 500, the resin applied on the polarization plate POL may be prevented from flowing to the outside through the through hole 777. In addition, since the hole cover 500 is made of a transparent material, light incident on the camera module 600 placed therebelow may normally pass through.

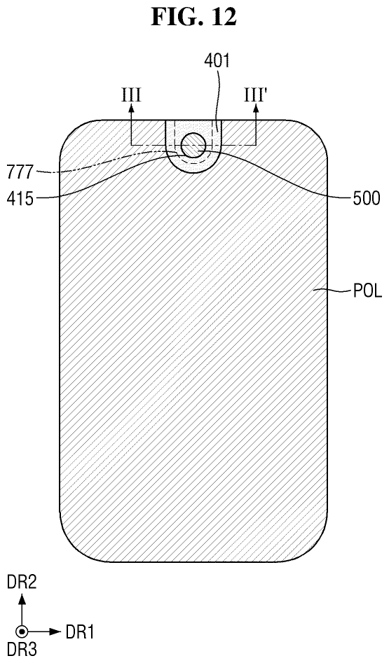

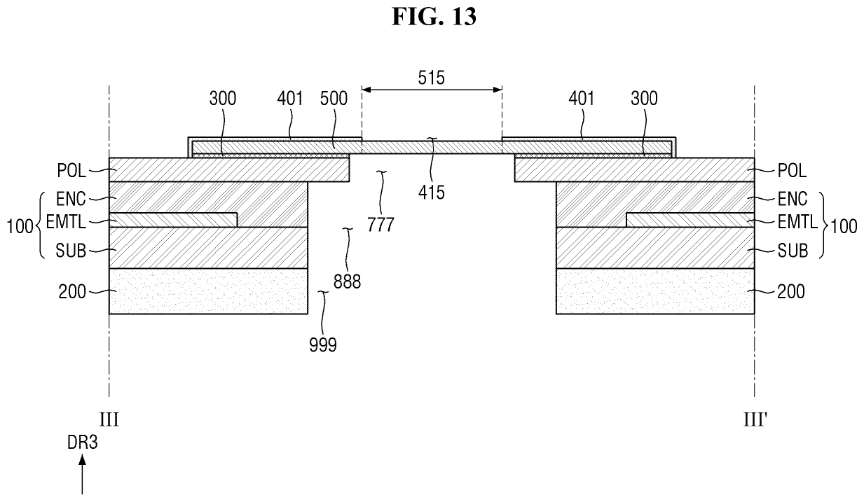

FIGS. 12 and 13 are views illustrating a method of manufacturing a display device according to embodiment. Here, FIG. 13 is a cross-sectional view taken along line III-III′ of FIG. 12.

Hereinafter, a method of manufacturing a display device according to an embodiment will be described based on FIGS. 4, 5, 12, 13, 8, 9, 10, and 11.

First, as illustrated in FIGS. 4 and 5 described above, a passivation layer 200 may be disposed on the lower surface of the display panel 100, and a polarization plate POL may be disposed on the upper surface of the display panel 100. A detailed description thereof is given in reference to FIGS. 4 and 5 and the related description described above.

Next, as illustrated in FIGS. 12 and 13, an adhesive layer 300, a hole cover 500, and a first light blocking layer 401 may be disposed on the polarization plate POL. For example, the adhesive layer 300, the hole cover 500, and the first light blocking layer 401 may be attached to each other to form one component (e.g., a hole cover member). In other words, the adhesive layer 300, the hole cover 500, and the first light blocking layer 401 may be attached to each other and provided as a single component (e.g., the hole cover member). For example, the hole cover member may include the hole cover 500, the adhesive layer 300, and the first light blocking layer 401.

Subsequently, as illustrated in FIGS. 8 and 9 described above, a second light blocking layer 402 may be disposed on the polarization plate POL along the edge of the polarization plate POL. A detailed description thereof is given in reference to FIGS. 8 and 9 and the related description described above.

Thereafter, as illustrated in FIGS. 10 and 11 described above, a window WD may be disposed on the hole cover 500, the polarization plate POL, the first light blocking layer 401, and the second light blocking layer 402. A detailed description thereof is given in reference to FIGS. 10 and 11 and the related description described above.

It will be able to be understood by one of ordinary skill in the art to which the present disclosure belongs that the present disclosure may be implemented in other specific forms without changing the technical spirit or essential features of the present disclosure. Therefore, it is to be understood that the exemplary embodiments described above are illustrative rather than being restrictive in all aspects. It is to be understood that the scope of the present disclosure is defined by the claims rather than the detailed description described above and all modifications and alterations derived from the claims and their equivalents fall within the scope of the present disclosure.

What is claimed is:

1. A display device comprising:
a display panel;
a polarization plate disposed on the display panel and having a through hole;
a hole cover disposed on the polarization plate to cover the through hole of the polarization plate;
a light blocking layer disposed on the hole cover and the polarization plate; and
a window on the polarization plate, the hole cover, and the light blocking layer,
wherein at least a portion of the light blocking layer is disposed between the hole cover and the window.

2. The display device of claim 1,
wherein the hole cover is disposed between the through hole of the polarization plate and the window.

3. The display device of claim 1,
wherein the light blocking layer comprises:
a first light blocking layer disposed on the hole cover and having an opening defining a transmission area of the hole cover; and
a second light blocking layer disposed on an edge of the polarization plate.

4. The display device of claim 3,
wherein the transmission area of the hole cover is disposed above the through hole of the polarization plate.

5. The display device of claim 3,
wherein the first light blocking layer is disposed on an edge of the hole cover.

6. The display device of claim 3,
wherein the first light blocking layer and the second light blocking layer are integral.

7. The display device of claim 3,
wherein the first light blocking layer is further disposed on a side of the hole cover.

8. The display device of claim 3,
further comprising an adhesive layer disposed between the polarization plate and the hole cover.

9. The display device of claim 8,
wherein the polarization plate and the hole cover are attached by the adhesive layer.

10. The display device of claim 8,
wherein the first light blocking layer is further disposed on a side of the adhesive layer.

11. The display device of claim 1,
wherein the hole cover is made of a transparent material.

12. The display device of claim 11,
wherein the hole cover includes at least one material selected from transparent glass, transparent acrylic, transparent urethane, and transparent polymethylmethacrylate (PMMA).

13. The display device of claim 1,
wherein the display panel has a through hole, and
wherein the through hole of the display panel is disposed below the through hole of the polarization plate.

14. The display device of claim 1,
further comprising a passivation layer disposed on a side of the polarization plate with the display panel interposed between the polarization plate and the passivation layer.

15. The display device of claim 14,
wherein the passivation layer has a through hole, and
wherein the through hole of the passivation layer is disposed below the through hole of the polarization plate.

16. A method of manufacturing a display device, the method comprising:
placing a polarization plate having a through hole on a display panel;
placing a hole cover on the polarization plate to cover the through hole of the polarization plate;
placing a light blocking layer on the polarization plate and the hole cover; and
placing a window on the light blocking layer,
wherein at least a portion of the light blocking layer is disposed between the hole cover and the window.

17. The method of claim 16,
wherein the hole cover is disposed between the through hole of the polarization plate and the window.

18. The method of claim 16,
wherein the placing of the light blocking layer comprises:
placing a first light blocking layer having an opening defining a transmission area of the hole cover on the hole cover; and
placing a second light blocking layer on an edge of the polarization plate.

19. The method of claim 18,
wherein the transmission area of the hole cover is disposed above the through hole of the polarization plate.

20. The method of claim 18,
wherein the first light blocking layer is disposed on an edge of the hole cover.

21. The method of claim 18,
wherein the first light blocking layer and the second light blocking layer are integrally formed.

22. The method of claim 18,
wherein the placing the light blocking layer further comprises placing the first light blocking layer on a side of the hole cover.

23. The method of claim 18,
further comprising placing an adhesive layer on the polarization plate and the hole cover.

24. The method of claim 23,
wherein the polarization plate and the hole cover are attached by the adhesive layer.

25. The method of claim 23,
wherein the placing the light blocking layer further comprises placing the first light blocking layer on a side of the adhesive layer.

26. The display device of claim 16,
wherein the hole cover is made of a transparent material.

27. The display device of claim 26,
wherein the hole cover includes at least one material selected from transparent glass, transparent acrylic, transparent urethane, and transparent polymethylmethacrylate (PMMA).

28. The method of claim 18,
wherein the placing the window comprises:
applying a resin on the hole cover, the polarization plate, the first light blocking layer, and the second light blocking layer; and
curing the resin.

29. A method of manufacturing a display device, the method comprising:
placing a polarization plate having a through hole on a display panel;
preparing a hole cover member including a first light blocking layer, a hole cover, and an adhesive layer;
placing the hole cover member on the polarization plate to cover the through hole of the polarization plate;
placing a second light blocking layer on the polarization plate; and
placing a window on the first light blocking layer,
wherein at least a portion of the first light blocking layer is disposed between the hole cover member and the window.

30. The method of claim 29,
wherein the first light blocking layer is disposed on the hole cover to define a transmission area of the hole cover.

31. The method of claim 29,
wherein the hole cover is made of a transparent material.
